(19) United States
(12) Patent Application Publication
(10) Pub. No.: US 2024/0128210 A1
(43) Pub. Date: Apr. 18, 2024

(54) Thermally Conductive IC Spacer with Integrated Electrical Isolation

(71) Applicant: Texas Instruments Incorporated, Dallas, TX (US)

(72) Inventors: Amit Ashara, Dallas, TX (US); Jeffrey West, Dallas, TX (US); Wai Lee, Dallas, TX (US)

(21) Appl. No.: 18/217,039

(22) Filed: Jun. 30, 2023

Related U.S. Application Data
(60) Provisional application No. 63/416,184, filed on Oct. 14, 2022.

(51) Int. Cl. H01L 23/00

(52) U.S. Cl. CPC H01L 24/05; H01L 24/26; H01L 24/29; H01L 24/32; H01L 2224/05551; H01L 2224/05552; H01L 2224/05567; H01L 2224/05647; H01L 2224/26145; H01L 2224/2929; H01L 2224/29339; H01L 2224/32245; H01L 2924/0665

(57) ABSTRACT

The present disclosure introduces an integrated circuit (IC) device that includes a plurality of metal features in a first metal layer over and electrically connected to a semiconductor substrate, an intermetal dielectric (IMD) layer over the first metal layer, and a second metal layer over the first metal layer and electrically isolated from the first metal layer by the IMD layer. The second metal layer includes a plurality of thermal contacts separated by portions of a top dielectric layer. Each thermal contact has an upper surface with a dielectric-free area.

### BACKGROUND OF THE DISCLOSURE

An integrated circuit (IC) device having high-voltage (HV) transistors can generate heat that, when excessive in degree and/or duration, can degrade performance and/or useful lifetime of the IC device. Accordingly, there have been many attempts at different ways to monitor the temperature of such devices utilizing various types of typically low-voltage (LV) sensing devices. However, these temperature sensing schemes exhibit degraded thermal responses due to thermal conduction limitations of materials utilized to electrically isolate the LV sensing device from the HV heat-generating device.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces an IC device that includes a plurality of metal features in a first metal layer over and electrically connected to a semiconductor substrate, an intermetal dielectric (IMD) layer over the first metal layer, and a second metal layer over the first metal layer and electrically isolated from the first metal layer by the IMD layer. The second metal layer includes a plurality of thermal contacts separated by portions of a top dielectric layer. Each thermal contact has an upper surface with a dielectric-free area.

The present disclosure also introduces a method of manufacturing an IC device. The method includes forming a first metal layer over and electrically connected to a semiconductor substrate, forming an IMD layer over the first metal layer, and forming a second metal layer over the first metal layer and electrically isolated from the first metal layer by the IMD layer. The second metal layer includes a plurality of thermal contacts separated by portions of a top dielectric layer and having upper surfaces with dielectric-free areas.

These and additional aspects of the present disclosure are set forth in the description that follows, and/or may be learned by a person having ordinary skill in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a sectional view of a portion of an example implementation of an IC device in an intermediate stage of manufacture according to one or more aspects of the present disclosure.

FIG. 2 is a plan view of a portion of an example implementation of the IC device shown in FIG. 1 according to one or more aspects of the present disclosure.

FIG. 3 is a sectional view of the IC device shown in FIG. 1 in a subsequent stage of manufacture according to one or more aspects of the present disclosure.

FIG. 4 is a sectional view of the IC device shown in FIG. 3 in a subsequent stage of manufacture according to one or more aspects of the present disclosure.

FIG. 5 is a sectional view of the IC device shown in FIG. 4 in a subsequent stage of manufacture according to one or more aspects of the present disclosure.

FIG. 6 is a plan view of a portion of an example implementation of the IC device shown in FIG. 5 according to one or more aspects of the present disclosure.

FIG. 7 is a plan view of a portion of another example implementation of the IC device shown in FIG. 5 according to one or more aspects of the present disclosure.

FIG. 8 is a sectional view of the IC device shown in FIG. 5 in a subsequent stage of manufacture according to one or more aspects of the present disclosure.

FIG. 9 is a sectional view of the IC device shown in FIG. 8 in a subsequent stage of manufacture according to one or more aspects of the present disclosure.

FIG. 10 is a sectional view of the IC device shown in FIG. 9 in a subsequent stage of manufacture according to one or more aspects of the present disclosure.

FIG. 11 is a sectional view of the IC device shown in FIG. 10 in a subsequent stage of manufacture according to one or more aspects of the present disclosure.

FIG. 12 is a plan view of a portion of an example implementation of the IC device shown in FIG. 11 according to one or more aspects of the present disclosure.

FIG. 13 is a schematic view of at least a portion of an example implementation of a multi-chip module according to one or more aspects of the present disclosure.

### DETAILED DESCRIPTION

It is to be understood that the following disclosure provides many different examples for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for simplicity and clarity, and does not in itself dictate a relationship between the various examples and/or configurations discussed. Moreover, the formation of a first feature over or on a second feature in the description that follows may include examples in which the first and second features are formed in direct contact, and may also include examples in which additional features may be formed interposing the first and second features, such that the first and second features may not be in direct contact.

In general, the present disclosure introduces a spacer die that may be utilized to provide electrical isolation between a temperature sensor operating in a low-voltage domain and, for example, a lead frame portion connected to a high-voltage terminal of a device the temperature of which is monitored by the temperature sensor. The spacer die has a semiconductor substrate and a metal interconnect stack connected to the substrate, and a relatively thick dielectric layer over the metal layers. The thick dielectric layer provides high-voltage isolation between the semiconductor substrate and the temperature sensor, while the metal layers reduce the thermal resistance between the semiconductor substrate and the temperature sensor. The spacer die includes metal layers, vias, and contacts that implement the interconnect stack, but need not include any active components such as transistors, such that the spacer die may be free of implants, gates, moats, or other transistor components. Thus, the spacer die may operate as an electrically passive component providing heat transfer from the lead frame portion to the temperature sensor while also providing conductive isolation. While such examples may be expected to provide a robust solution to measure the temperature of a high-voltage device, no particular result is a requirement unless explicitly recited in a particular claim.

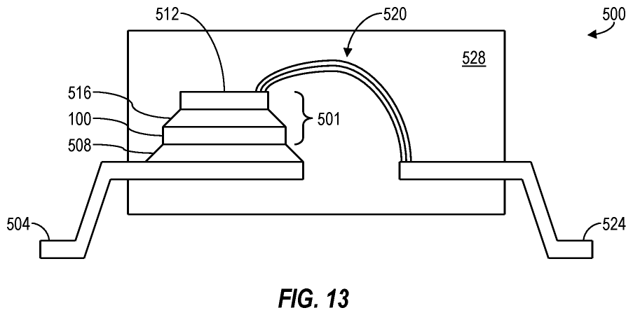

FIG. 13 illustrates an example of a packaged device 500 that includes a multi-chip module (MCM) 501, a first leadframe portion 504 and a second leadframe portion 524 within an encapsulant 528. The MCM 501 incorporates a temperature sensor 512 and an IC device 100 that implements a spacer die such as described above. The IC device 100 is sometimes referred to as spacer die 100. The first leadframe portion 504, which is sometimes referred to as a lead 504 for brevity, may be attached to a high-voltage lead of a heat-generating device (not shown) for which temperature is being monitored by the MCM 501. The IC device 100 is attached to the lead 504 by a thermally conductive adhesive (e.g., silver-impregnated epoxy) 508. The temperature sensor 512 is similarly attached to the IC device 100 by thermally conductive adhesive 516, which may be of the same or different type of adhesive as the thermally conductive adhesive 508. One or more wires 520 are connected between the temperature sensor 512 and the second leadframe portion 524, which may include multiple leads that are conductively separated and may sometimes be referred to as leads 524. For example, the wires 520 may include three wires extending between the leads 524, one each for power, ground, and a voltage indicative of a temperature sensed by the temperature sensor 512, although other implementations may have more or fewer than three wires. The encapsulant 528 provides mechanical support, environmental isolation, and electrical insulation for the assembly.

The lead 504 may be connected to a device operating in a high-voltage domain, e.g., 1 kilovolt (kV) or more, while the temperature sensor 512 may operate in a low-voltage domain, e.g., 5 volts (V) or less. Electrical isolation between the lead 504 and the leads 524 is facilitated by various features of the spacer die 100. The spacer die 100 also includes features that reduce the thermal resistance between the lead 504 and the temperature sensor 512 that would otherwise result from only a thick dielectric stack.

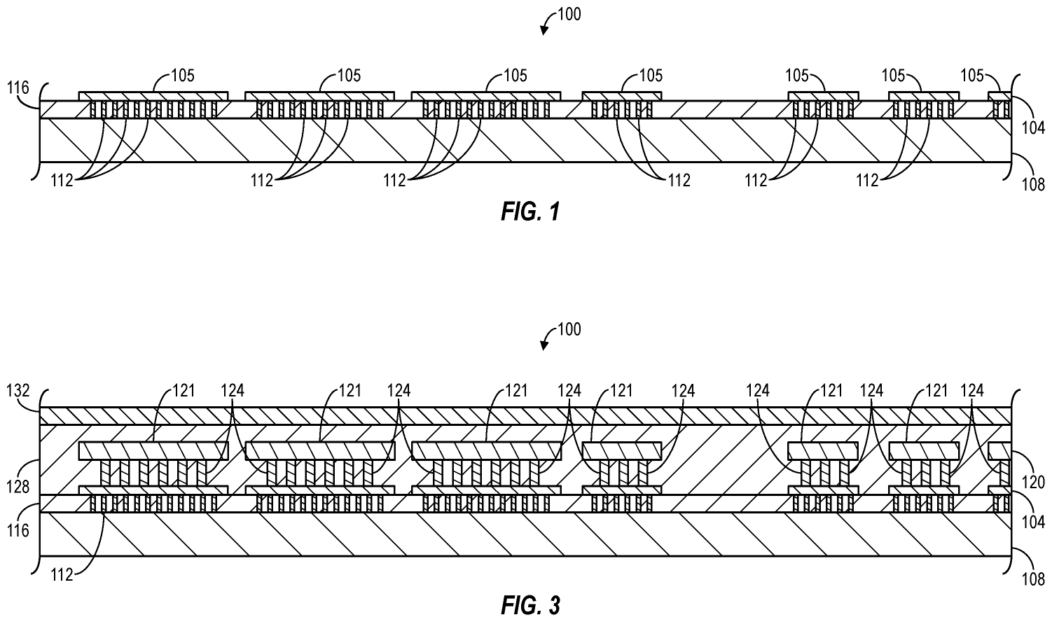

Turning to FIG. 1, a sectional view is provided of a portion of an example implementation of the spacer die 100 in an intermediate stage of manufacture according to one or more aspects of the present disclosure. The spacer die 100 includes a first metal layer 104 connected to a semiconductor substrate 108 by contacts 112. The connection between the contacts 112 and the substrate 108 may include a silicide layer (not shown) between each of the contacts 112 and the substrate 108. The silicide layer, if present, may facilitate an electrical (e.g., conductive) connection between the first metal layer 104 and the substrate 108. A bottom dielectric layer 116 interposes the electrical contacts 112 and portions of the first metal layer 104 above the substrate 108.

The substrate 108 may include silicon, among other possible examples, and may be thinned to a thickness of about 7.5 mils after completion of the spacer die 100. The substrate 108 may have a resistivity of 0.014-175 Ohm-centimeters (Ω-cm). In an example implementation, the resistivity of the substrate 108 is 150 Ω-cm.

The bottom dielectric layer 116 may include silicon oxide, e.g., formed from tetraethyl orthosilicate (TEOS), and/or other dielectric materials, and may have a thickness of 0.8-1.2 micrometers (μm). The electrical contacts 112 may be tungsten, aluminum, and/or other materials having electrical and thermal conductivities similar to tungsten and/or aluminum, and may have a width of 0.15-0.3 μm, among other examples. The first metal layer 104 may include aluminum having a thickness of 0.5 μm, although other materials and thicknesses are also possible.

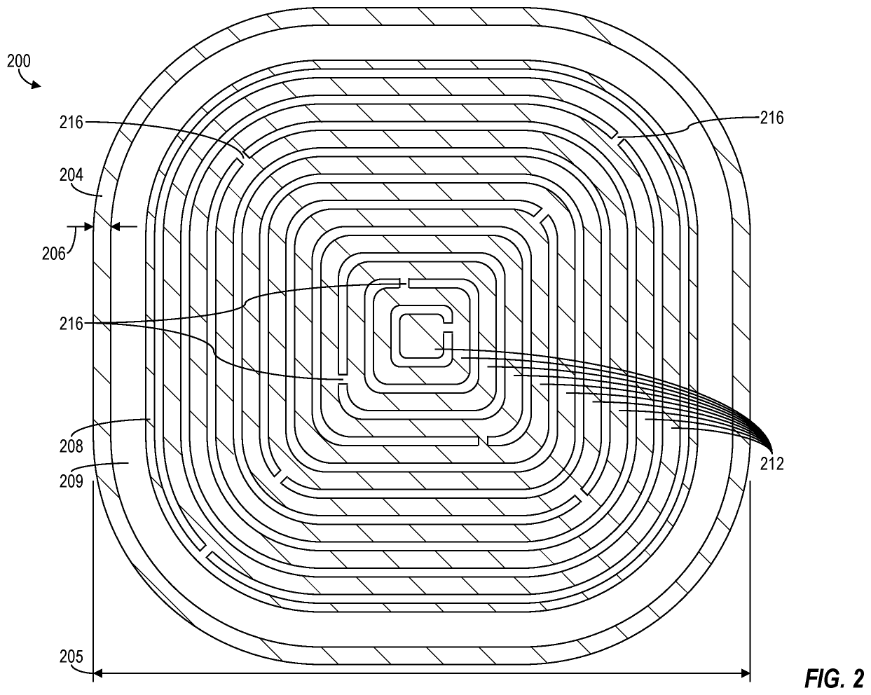

FIG. 2 is a plan view of one example implementation of the first metal layer 104 (designated in FIG. 2 by reference number 200) according to aspects of the present disclosure. The first metal layer 200 includes a relatively dense population of horizontal interconnects 105 so as to maximize heat transfer from the substrate 108. In FIG. 2, the horizontal interconnects 105 of the first metal layer 200 are a plurality of concentric traces. For example, an outer concentric trace 204 may be a ring having a rounded square shape (e.g., an annular “squircle”) with a width 205 of 1-1.500 millimeters (mm) and a linewidth 206 of 5-20 μm. Another concentric trace 208 having a linewidth of 10-20 μm is separated from the trace 204 by 5-10 μm. The remaining concentric traces 212 have linewidths of 10-20 μm and are spaced apart by 2-10 μm. The space 209 between the two outermost traces 204, 208 may provide stress relief during subsequent dicing operations. In other implementations, the space 209 may be as small as 2 μm.

The concentric traces 204, 208, 212 may not contact each other, such that they are only in electric contact indirectly via the electrical contacts 112 and the substrate 108. However, as depicted in FIG. 2, one or more of the concentric traces 204, 208, 212 may be in direct contact via connecting portions 216 of the first metal layer 200.

The layout of the first metal layer 200 shown in FIG. 2 is merely an example, and other layouts are also within the scope of the present disclosure. For example, although only ten concentric traces 212 are depicted in the schematic example shown in FIG. 2, actual implementations within the scope of the present disclosure may include twenty, thirty, or more concentric traces. Moreover, the layout of the first metal layer 104 may not include concentric features as depicted in FIG. 2, but may instead include interconnected rows, columns, serpentines, and/or otherwise shaped horizontal interconnects 105. However the horizontal interconnects 105 are arranged, such layouts nonetheless form a relatively dense array of metal features so as to maximize heat transfer from the substrate 108. For example, the metal features of the example first metal layer 200 depicted in FIG. 2 cover about 60% of the total area inside the outer periphery of the outer trace 204. However, in production implementations, the percentage of the area inside the outer periphery of the outer trace 204 may be higher than 60%, perhaps ranging between 70-85%, among other examples.

FIG. 3 is a sectional view of the IC device 100 shown in FIG. 1 in a subsequent stage of manufacture according to one or more aspects of the present disclosure. The IC device 100 now includes a second metal layer 120 connected to the first metal layer 104 by a plurality of vias 124. A first 1 MB layer 128 overlies the second metal layer 120 and interposes the vias 124, portions of the first metal layer 104, and portions of the second metal layer 120. An etch stop layer 132 has been formed on the first 1 MB layer 128.

The first 1 MB layer 128 may be silicon oxide and/or other dielectric materials, and may have a thickness of 5-9 The vias may be tungsten, aluminum, and/or other materials having electrical and thermal conductivities similar to tungsten and/or aluminum, and may have a width of 0.5-1.0 μm, among other examples. The second metal layer 120 may be aluminum having a thickness of 1.5 although other materials and thicknesses are also possible.

Similar to the first metal layer 104, the second metal layer 120 includes a relatively dense population of horizontal interconnects 121 so as to maximize heat transfer from the first metal layer 104. For example, the layout of the horizontal interconnects 121 of the second metal layer 120 may be similar to the layout of the concentric traces 204, 208, 212 depicted in FIG. 2. In an example implementation, the layout and composition of the second metal layer 120 may be identical to those of the first metal layer 104, except that the second metal layer 120 is two to three times thicker than the first metal layer 104. Such repeated design features can reduce production complexities.

Although depicted a single layer in FIG. 3, the first IMD layer 128 may be more than one layer, such as a combination of one or more low-stress silicon oxide (LS TEOS) layers and one or more high-stress silicon oxide (HS TEOS) layers. The etch stop layer 132 may be silicon oxynitride (SiON) and/or other etch stop materials, and may have a thickness of 0.5-1.5 μm. Examples of low-stress silicon oxide and high-stress silicon oxide may be found in U.S. Pat. No. 11,495,658 (“the '658 patent”), incorporated herein by reference in its entirety.

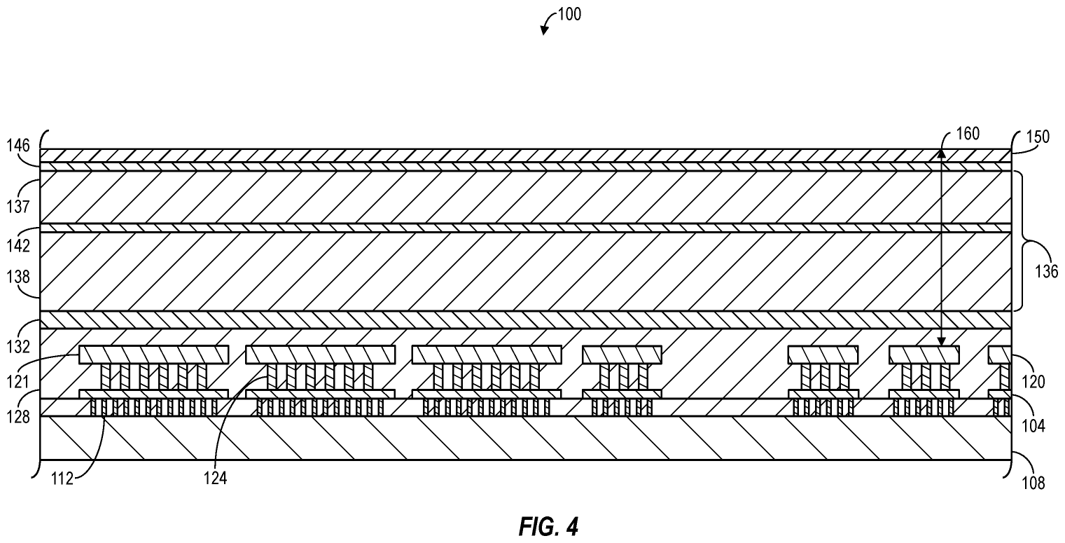

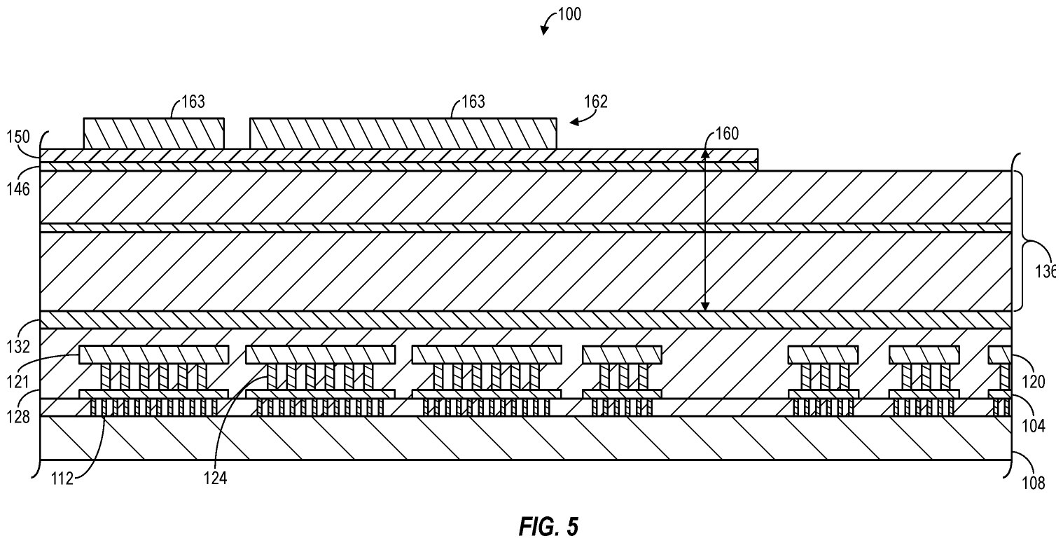

FIG. 4 is a sectional view of the IC device 100 shown in FIG. 3 in a further subsequent stage of manufacture according to one or more aspects of the present disclosure. The IC device 100 now includes a second IMD layer 136 vertically divided into an upper portion 137 and a lower portion 138 by an etch assist layer 142. An electrically insulating layer 146 overlies the second IMD layer 136, and another electrically insulating layer 150 overlies the electrically insulating layer 146. The insulating layers 146, 150 collectively form a lower-bandgap dielectric layer that advantageously provides reliability for the second IMD layer 136 by reducing an electric field at edges of the subsequently formed third metal layer 162 (see FIG. 5).

One or both portions 137, 138 of the second IMD layer 136 may be more than one layer, such as a combination of one or more LS TEOS layers and one or more HS TEOS layers. The etch assist layer 142 and the insulating layer 146 may each include SiON and/or other etch stop/assist materials, and may each have a thickness of 0.2-0.4 μm. The insulating layer 150 may include silicon nitride (SiN) and/or other insulating materials, and may have a thickness of 0.5-1.0 μm.

The combined thickness 160 of the insulating layer 150, the insulating layer 146, the second 1 MB layer 136, the etch stop layer 132, and the portion of the first IMD layer 128 overlying the second metal layer 120 may be 18-22 μm. This thickness 160 is selected to ensure electrical isolation between the lower metal layers 104, 120 and the upper, third metal layer 162 (see FIG. 5) that will be formed on the insulating layer 150 while managing accumulated stress. Additional details regarding forming thick dielectric layers while managing stress may be found in the '658 patent.

FIG. 5 is a sectional view of the IC device 100 shown in FIG. 4 in a further subsequent stage of manufacture in which the third metal layer 162 has been formed on the insulating layer 150, and portions of the insulating layer 150 and the insulating layer 146 have subsequently been removed. The third metal layer 162 comprises a plurality of horizontal traces 163 serving as thermal contacts to which a temperature sensor device will be attached via conductive (electrically and/or thermally) adhesive. The horizontal traces 163 are electrically isolated from the lower metal layers 104, 120, but may thermally communicate with the lower metal layers 104, 120 through the IMD layer 128. As used herein, “electrically isolated” means there is no conductive connection between the horizontal traces 163 and the lower metal layers 104, 120.

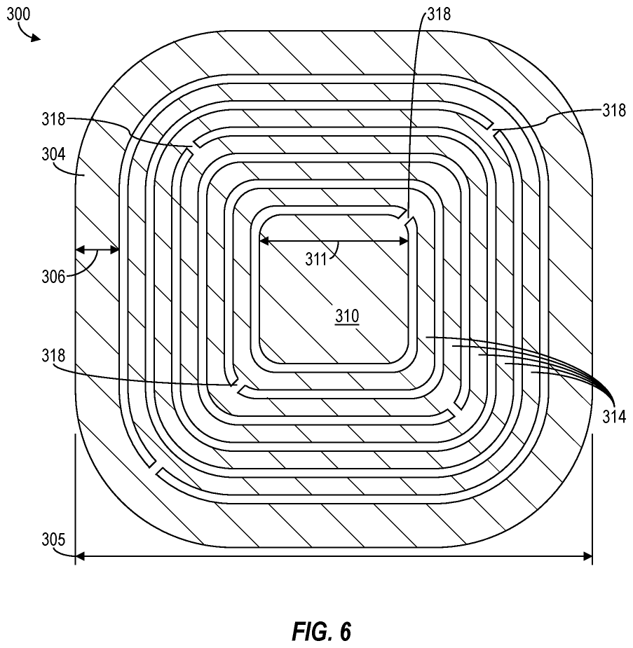

As with the first and second metal layers 104, 120, the horizontal traces 163 of the third metal layer 162 form a relatively dense population so as to facilitate heat transfer received from the lower metal layers 104, 120 through the insulating layer 150, the insulating layer 146, the second IMD layer 136, the etch stop layer 132, and the portion of the first 1 MB layer 128 overlying the second metal layer 120 (e.g., through the stack of dielectric layers of thickness 160). In other words, the composite stack including the various metal structures and dielectric layers can provide electrical isolation greater than 1 kV rms (root-mean-square) while also providing sufficiently low thermal resistance such that the lead 504 can communicate heat to the temperature sensor 512 without operationally significant delay. FIG. 6 is a plan view of one such example implementation of the third metal layer 162 (designated in FIG. 6 by reference number 300) according to aspects of the present disclosure.

In FIG. 6, the horizontal traces of the third metal layer 300 include a plurality of concentric traces. For example, an outer trace 304 may be an annular squircle with a width 305 of 0.8-1.2 mm and a linewidth 306 of 100-125 μm. In this example, the horizontal traces of the third metal layer 300 also include a central contact pad 310 in the shape of a squircle having a width 311 of 500-700 μm. The remaining horizontal traces of the third metal layer 300 are contact traces 314 between the central contact pad 310 and the outer trace 304. In the illustrated example, the contact traces are concentric, though other patterns are within the scope of the disclosure. Each contact trace 314 may have a linewidth of 10-20 μm and may be separated from the neighboring contact traces 314, the outer trace 304, and/or the central contact pad 310 by 3-5 μm, although other dimensions are also possible. However, the spaces between the contact traces 314, the central contact pad 310, and the outer trace 304 also result in the formation of grooves when a protective overcoat (PO) is formed over the third metal layer 162. The grooves may aid in retarding or preventing excessive outward flow of die attach material (e.g., the aforementioned conductive adhesive), as further described below.

As described above, the lower metal layers 104, 120 may each comprise concentric traces 212. Each contact trace 314 of the third metal layer 162 may have a pattern or layout following that of a corresponding one of the concentric traces 212 of the lower metal layers 104, 120. In an example implementation, each concentric trace 212 of the lower metal layers 104, 120 extends laterally outward beyond the outer boundary of the corresponding contact trace 314 and laterally inward beyond the inner boundary of the corresponding contact trace 314. Thus, the lateral edges of each contact trace 314 do not overhang the lateral edges of the corresponding concentric traces 212.

In some examples, the contact traces 304, 314 and the central contact pad 310 may not contact each other, such that they are only in electrical contact after the conductive adhesive is applied when attaching the temperature sensor device. In other examples, as depicted in FIG. 6, the contact traces 304, 314 and the central contact pad 310 may be in direct contact via connecting portions 318 of the third metal layer 162/300. As depicted in FIG. 6, at least some of the connecting portions 318 may be positioned near the “corners” of the layout (i.e., along diagonal directions of the layout) where die attach bleed-out is minimal and not expected to flow over these outer connecting portions 318, relative to placement of the connecting portions 318 nearer the midlines of the layout.

The layout of the third metal layer 300 shown in FIG. 6 is merely an example, and other layouts are also within the scope of the present disclosure. For example, although only five contact traces 314 are depicted in the schematic example shown in FIG. 6, actual implementations within the scope of the present disclosure may include twenty, thirty, or more concentric traces. Moreover, the layout of the third metal layer 162 may not include concentric features as depicted in FIG. 6, but may instead include interconnected rows, columns, serpentines, and/or otherwise shaped horizontal traces 163. However the horizontal traces 163 are arranged, such layouts nonetheless form a relatively dense array of metal features so as to maximize heat transfer to the temperature sensor. For example, the percentage of the area inside the outer periphery of the outer trace 304 that is occupied by metal may range between 60-65%, among other examples.

In the examples described above, the metal layers 104, 120, 162 are described as being formed of aluminum. However, other conductive materials are also possible. For example, one or more of the metal layers 104, 120, 162 may be made with damascene copper. In such implementations, the electrically insulating layers 146, 150 may not exist, such that the damascene copper may be formed directly on the second IMD layer 136.

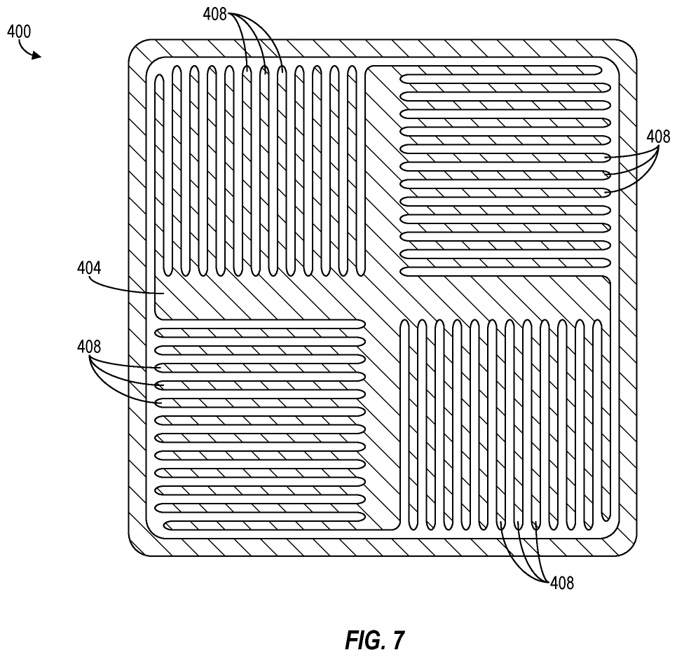

FIG. 7 is a plan view of another example implementation of the third metal layer 162 according to aspects of the present disclosure. FIG. 7 provides an example layout 400 of the horizontal traces 163 as an alternative to the concentric ring arrangement depicted in FIG. 6. For example, the horizontal traces 163 of the layout 400 include a central, cross-shaped interconnect 404 that includes cross members each having a width of 10-20 μm. The horizontal traces 163 of the layout 400 also include, within each quadrant defined by the cross-shaped interconnect 404, a plurality of elongated traces 408 each connected to the cross-shaped interconnect 404 and having a width of 5-10 μm. The direction of elongation of the traces 408 alternates by quadrant. Each trace 408 may be spaced apart from other traces 408 by 3-5 μm. FIG. 7 is also schematically depictive of an alternative to the layout of the first and second metal layers 104, 120 depicted in FIG. 2.

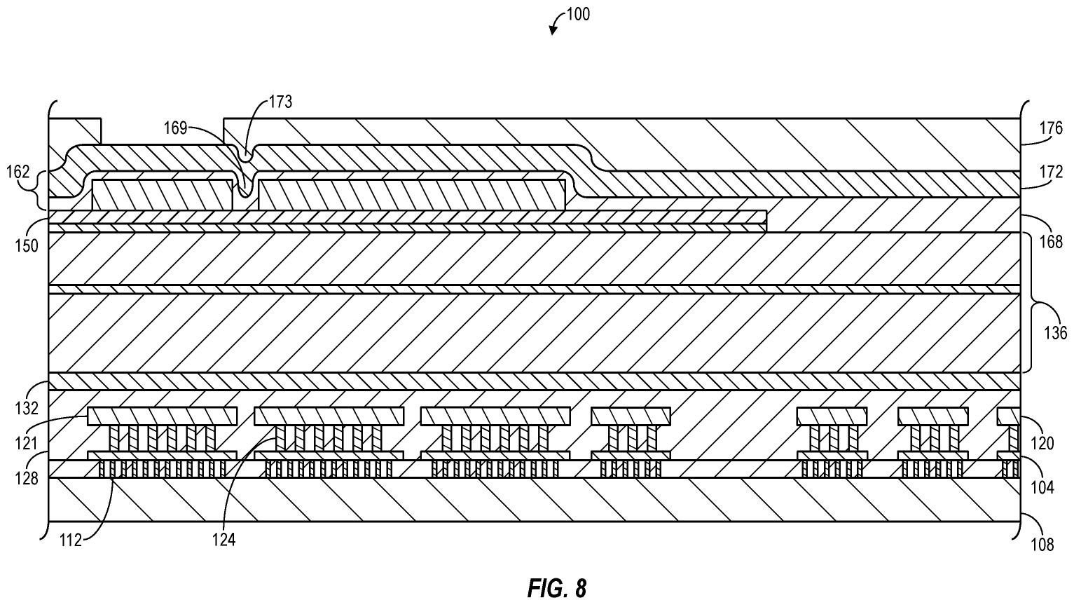

FIG. 8 is a sectional view of the IC device 100 shown in FIG. 5 in a further subsequent stage of manufacture according to aspects of the present disclosure. A silicon oxide layer 168 has been formed on the third metal layer 162 and the exposed portions of the insulating layer 150 and the second IMB layer 136. An SiON layer 172 has been formed over the silicon oxide layer 168. A patterned photoresist layer 176 has been formed over the SiON layer 172.

Forming the silicon oxide layer 168 creates a valley 169 between the horizontal traces 163. Forming the SiON layer 172 in the valley 169 of the silicon oxide layer 168 creates a similar valley 173. The valley 173 in the SiON layer 172 may contribute to the above-described grooves in the subsequently formed PO that may aid in preventing excessive outward flow of die attach material.

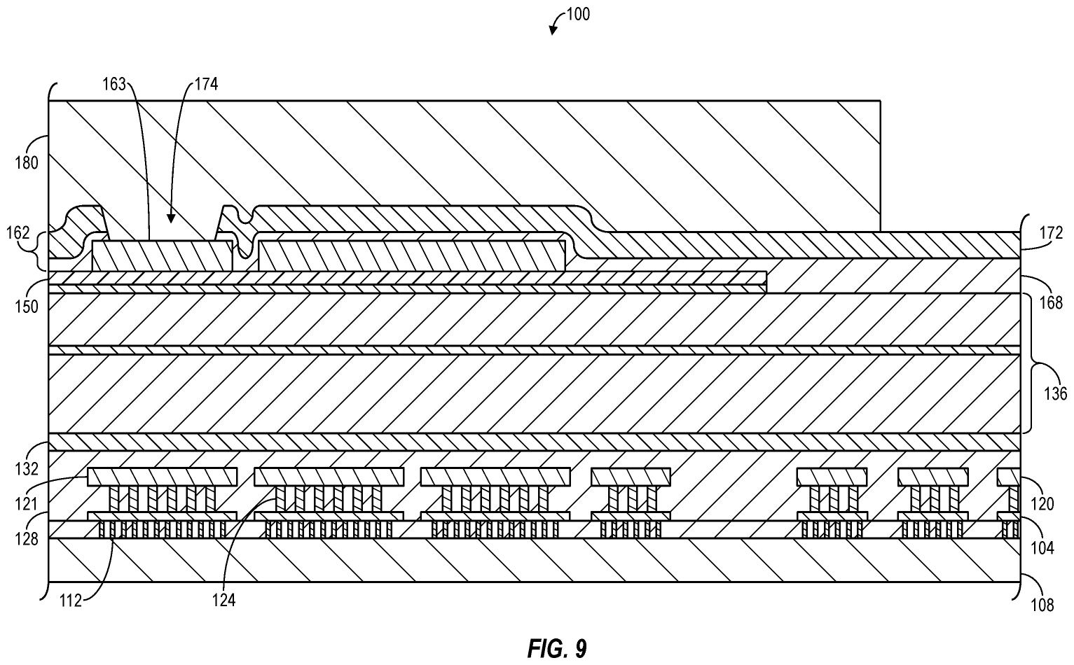

FIG. 9 is a sectional view of the IC device 100 shown in FIG. 8 in a further subsequent stage of manufacture in which the patterned photoresist layer 176 shown in FIG. 8 has been used to etch openings 174 in the SiON layer 172 and the silicon oxide layer 168 to expose at least a portion of the upper surfaces of the horizontal traces 163. As depicted in FIG. 9, one or more of the horizontal traces 163 (e.g., the outer trace 304 shown in FIG. 6) may remain covered by the non-etched portions of the SiON layer 172 and the silicon oxide layer 168. A patterned photoresist layer 180 has also been formed over portions of the SiON layer 172, including over the exposed upper surfaces of the horizontal traces 163.

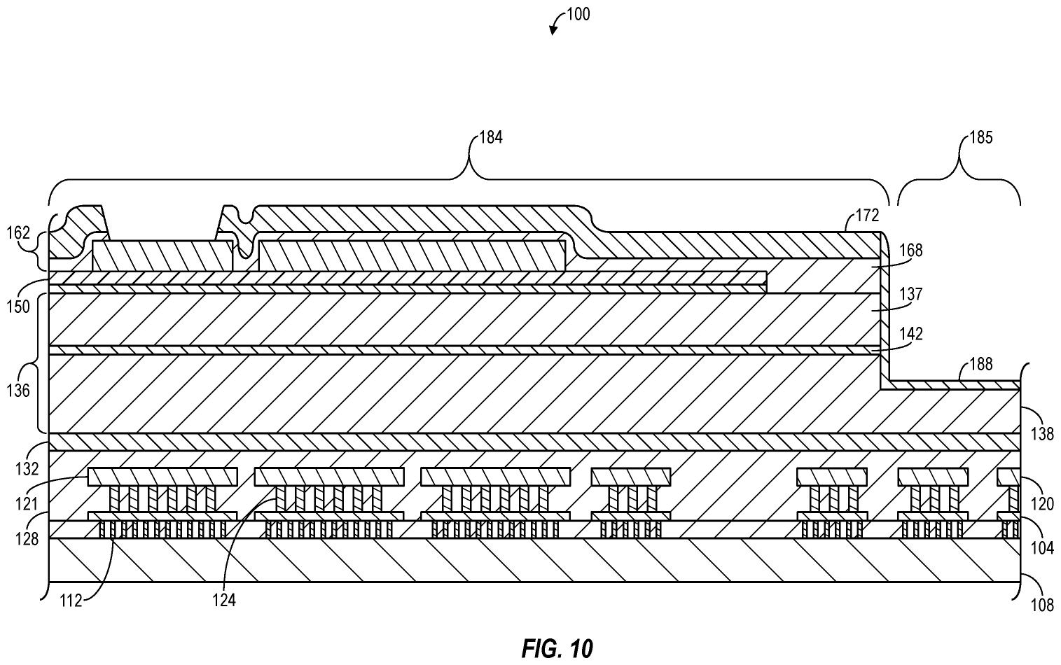

FIG. 10 is a sectional view of the IC device 100 shown in FIG. 9 in a further subsequent stage of manufacture in which the patterned photoresist layer 180 shown in FIG. 9 has been used to etch through the SiON layer 172, the silicon oxide layer 168, the upper portion 137 of the second IMD layer 136, and the etch assist layer 142, and partially into the lower portion 138 of the second 1 MB layer 136. Such etching forms a plateau 184, or mesa, and a trough 185, or valley, for the purpose of dicing after the chip processing is complete. For instance, in some implementations, a dicing blade might otherwise cause cracking in dielectric layers when the IC device 100 is singulated in the absence of the thinner trough 185. In some implementations, the etching that creates the trough 185 may etch down past the top surface of the second metal layer 120 in the region of a scribelane surrounding each die.

FIG. 10 also depicts the formation of an SiON layer 188 on surfaces of the SiON layer 172, the silicon oxide layer 168, the upper portion 137 of the second IMD layer 136, the etch assist layer 142, and the lower portion 138 of the second 1 MB layer 136 exposed by the etching that formed the plateau 184. For example, an optional heat treatment may be performed in an N₂ ambient at 400° C. for 30 minutes to anneal the metal features and drive residual moisture from the dielectric layers to reduce wafer bow. An optional NH₃ plasma treatment may be used to convert a portion of the exposed surfaces of the second IMD layer 136 to form the SiON layer 188 to reduce moisture uptake that could otherwise reduce device reliability and/or lifetime in high-voltage (e.g., greater than 1 kV) applications. In other implementations, the SiON layer 188 may instead be an Al₂O₃ layer formed by alternating layer deposition (ALD).

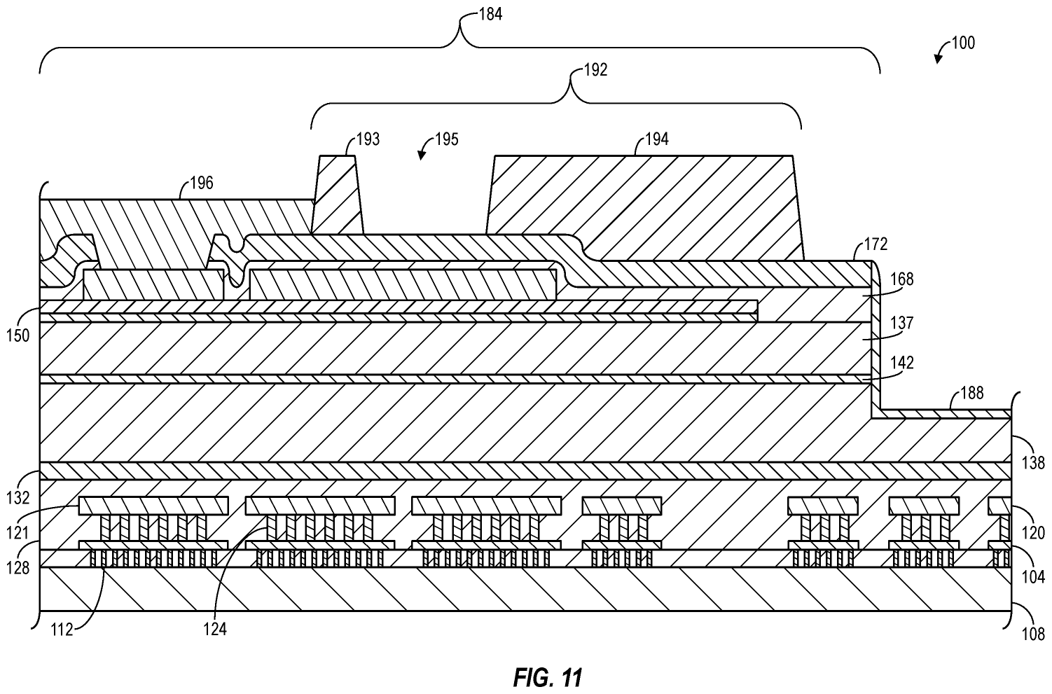

FIG. 11 is a sectional view of the IC device 100 shown in FIG. 10 in a further subsequent stage of manufacture in which a polyimide (PI) dam 192 has been formed on the SiON layer 172 around the perimeter of the plateau 184. The height of the PI dam 192 may be 5-20 μm. FIG. 11 also depicts the conductive adhesive (e.g., silver-impregnated epoxy) 196 that has been dispensed on the exposed upper surfaces of the third metal layer 162 just prior to the temperature sensor 512 being attached. The PI dam 192 may include an inner portion 193 serving as an initial barrier to overflow of the conductive adhesive 196, as well as an outer portion 194 surrounding the inner portion 193 and spaced apart from the inner portion 193 by at least 20 μm. The inner and outer portions 193, 194 of the PI dam 192 collectively define an annulus-shaped overflow chamber 195 to contain any of the conductive adhesive 196 that may spill over the inner dam portion 193. The PI dam 192 prevents the overflow of conductive adhesive over the side of the plateau 184 that could otherwise cause lateral breakdown due to the resulting electrical fields between the conductive epoxy overflow region and the first lead 504.

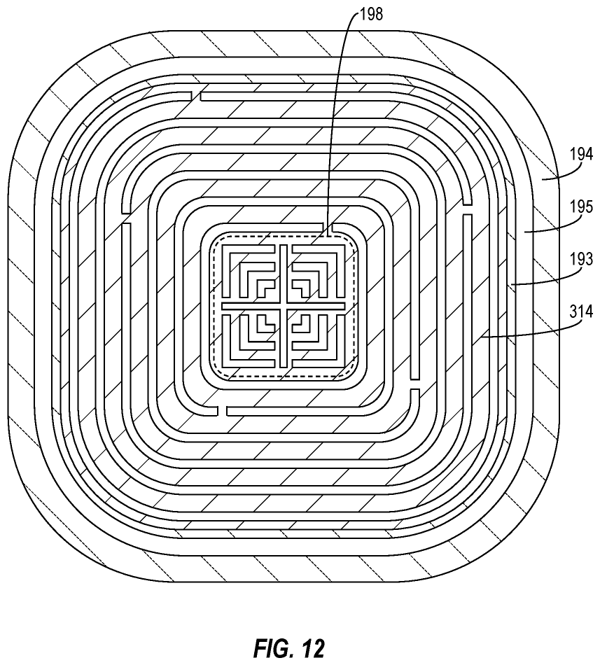

FIG. 12 is a plan view of an example implementation of the IC device 100 shown in FIG. 11, showing just the PI dam 192 and the exposed upper surfaces of the third metal layer 162. The inner dam portion 193 surrounds the exposed upper surfaces of the third metal layer 162, such as the outermost contact trace 314 shown in FIG. 6. The outer dam portion 194 surrounds the inner dam portion 193, defining the overflow chamber 195.

FIG. 12 also depicts a patterned area over the central contact pad 310. This pattern represents portions of the above-described PO having been removed from over the central contact pad 310. Such PO removal (POR) creates regions where conductive die attach can flow to allow both thermal and electronic conduction between the backside of the sensor die and the top metal plate 300 of the spacer die. Implementations within the scope of the present disclosure may include the PI dam 192, the POR grooves 198, or both.

Examples consistent with the disclosure provide rapid heat transfer between the lead 504 and the temperature sensor 512 (FIG. 13). Some baseline temperature sensing solutions rely on lateral heat transfer across a substrate such as a printed circuit board (PCB) between a heat source and a temperature sensor, with a spacing between the heat source and the sensor sufficient to ensure no voltage breakdown. Other baseline solutions rely on an organic dielectric such as polyimide to electrically insulate a high voltage heat source from a temperature sensor. In contrast, examples as described herein provide that the lower metal layers 104, 120 and the second IMD layer 136 as the electrical isolation between the third metal layer 162 and the lower metal layer 120 provide sufficient voltage isolation and also sufficient thermal conductivity so that a response time of the temperature sensor 512 is expected to be about one-half or less than that of such baseline solutions, and possibly one or two orders of magnitude less than such solutions. For example, implementations within the scope of the present disclosure for which the 1 MB layer 136 has a thickness of about 20 μm were modeled to have a 63% response time to a step temperature increase of about 1.1 seconds, versus about 2 seconds for a polyimide spacer solution. Thus, systems implementing a voltage-isolated temperature sensor consistent with the present disclosure are expected to be significantly more responsive to temperature changes than such baseline solutions.

In view of the entirety of the present disclosure, including the figures and the claims, a person having ordinary skill in the art will readily recognize that the present disclosure introduces an IC device comprising: a plurality of metal features in a first metal layer over and electrically connected to a semiconductor substrate; an 1 MB layer over the first metal layer; and a second metal layer over the first metal layer and electrically isolated from the first metal layer by the IMD layer, wherein the second metal layer comprises a plurality of thermal contacts separated by portions of a top dielectric layer, and wherein each thermal contact has an upper surface with a dielectric-free area.

The plurality of thermal contacts may be connected by connecting portions of the second metal layer.

The plurality of thermal contacts may comprise a central contact pad and a plurality of contact traces extending around the contact pad. The contact traces may overlie corresponding traces in the first metal layer. Lateral edges of each contact trace may not overhang lateral edges of the corresponding trace in the first metal layer. For example, each trace in the first metal layer may extend laterally outward beyond the outer boundary of the corresponding contact trace and laterally inward beyond the inner boundary of the corresponding contact trace.

The IC device may further comprise a third metal layer between the first metal layer and the substrate. The first and third metal layers may be electrically isolated from the second metal layer by the IMD layer. The first and third metal layers may be connected by a plurality of vias. A plurality of contacts may electrically connect the substrate to the third metal layer. The first and third metal layers may have a same layout.

The IMD layer may be a first IMD layer and the IC device may further comprise: a third metal layer between the first metal layer and the substrate; a second IMD layer between first and third metal layers; a plurality of vias extending through the second IMD layer and electrically connecting the first and third metal layers; a bottom dielectric layer between the third metal layer and the substrate; and a plurality of electrical contacts extending through the bottom dielectric layer and electrically connecting the third metal layer and the substrate.

The IC device may comprise a PI dam over the plurality of thermal contacts. An outer periphery of the PI dam may laterally surround the plurality of thermal contacts. The PI dam may comprise an inner portion and an outer portion surrounding the inner portion and defining an annulus-shaped overflow chamber between the inner and outer portions. The PI dam may have a height of 5-20 μm. The inner and outer portions of the polyimide dam may be spaced apart by at least 20 μm.

The IC device may not comprise any transistors.

The present disclosure also introduces a method of manufacturing an IC device, comprising: forming a first metal layer over and electrically connected to a semiconductor substrate; forming an IMD layer over the first metal layer; and forming a second metal layer over the first metal layer and electrically isolated from the first metal layer by the IMD layer, wherein the second metal layer comprises a plurality of thermal contacts separated by portions of a top dielectric layer and having upper surfaces with dielectric-free areas.

The plurality of thermal contacts may be connected by connecting portions of the second metal layer.

The plurality of thermal contacts may comprise a central contact pad and a plurality of contact traces extending around the contact pad. The contact traces may overlie corresponding traces in the first metal layer.

The method may further comprise forming a third metal layer between the first metal layer and the substrate. The first and third metal layers may be electrically isolated from the second metal layer by the IMD layer. The first and third metal layers may be connected by a plurality of vias. A plurality of contacts may electrically connect the substrate to the third metal layer. The first and third metal layers may have a same layout.

The method may further comprise forming a PI dam over the plurality of thermal contacts. An outer periphery of the PI dam may laterally surround the plurality of thermal contacts. The PI dam may comprise an inner portion and an outer portion surrounding the inner portion and defining an annulus-shaped overflow chamber between the inner and outer portions.

The manufactured IC device may not comprise any transistors.

The foregoing outlines features of several implementations so that a person having ordinary skill in the art may better understand the aspects of the present disclosure. A person having ordinary skill in the art should appreciate that they may readily use the present disclosure as a basis for designing or modifying other processes and structures for carrying out the same functions and/or achieving the same benefits of the examples introduced herein. A person having ordinary skill in the art should also realize that such equivalent constructions do not depart from the spirit and scope of the present disclosure, and that they may make various changes, substitutions and alterations herein without departing from the spirit and scope of the present disclosure.

The Abstract at the end of this disclosure is provided to permit the reader to quickly ascertain the nature of the technical disclosure. It is submitted with the understanding that it will not be used to interpret or limit the scope or meaning of the claims.

What is claimed is:

1. An integrated circuit (IC) device, comprising:
a plurality of metal features in a first metal layer over and electrically connected to a semiconductor substrate;
an intermetal dielectric layer over the first metal layer; and
a second metal layer over the first metal layer and electrically isolated from the first metal layer by the intermetal dielectric layer, wherein the second metal layer comprises a plurality of thermal contacts separated by portions of a top dielectric layer, and wherein each thermal contact has an upper surface with a dielectric-free area.

2. The IC device of claim 1 wherein the plurality of thermal contacts are connected by connecting portions of the second metal layer.

3. The IC device of claim 1 wherein the plurality of thermal contacts comprises a central contact pad and a plurality of contact traces extending around the contact pad.

4. The IC device of claim 3 wherein the contact traces overlie corresponding traces in the first metal layer.

5. The IC device of claim 4 wherein lateral edges of each contact trace do not overhang lateral edges of the corresponding trace in the first metal layer.

6. The IC device of claim 4 wherein each trace in the first metal layer extends laterally outward beyond an outer boundary of the corresponding contact trace and laterally inward beyond an inner boundary of the corresponding contact trace.

7. The IC device of claim 1 further comprising a third metal layer between the first metal layer and the substrate, wherein:
the first and third metal layers are electrically isolated from the second metal layer by the intermetal dielectric layer;
the first and third metal layers are connected by a plurality of vias; and
a plurality of contacts electrically connect the substrate to the third metal layer.

8. The IC device of claim 7 wherein the first and third metal layers have a same layout.

9. The IC device of claim 1 wherein the intermetal dielectric layer is a first intermetal dielectric layer and the IC device further comprises:
a third metal layer between the first metal layer and the substrate;
a second intermetal dielectric layer between first and third metal layers;
a plurality of vias extending through the second intermetal dielectric layer and electrically connecting the first and third metal layers;
a bottom dielectric layer between the third metal layer and the substrate; and
a plurality of electrical contacts extending through the bottom dielectric layer and electrically connecting the third metal layer and the substrate.

10. The IC device of claim 1 further comprising a polyimide dam over the plurality of thermal contacts, wherein an outer periphery of the polyimide dam laterally surrounds the plurality of thermal contacts.

11. The IC device of claim 10 wherein the polyimide dam comprises:
an inner portion; and
an outer portion surrounding the inner portion and defining an annulus-shaped overflow chamber between the inner and outer portions.

12. The IC device of claim 11 wherein:
the polyimide dam has a height of 5-20 μm; and
the inner and outer portions of the polyimide dam are spaced apart by at least 20 μm.

13. The IC device of claim 1 wherein the IC device does not comprise any transistors.

14. A method of manufacturing an integrated circuit (IC) device, comprising:
forming a first metal layer over and electrically connected to a semiconductor substrate;
forming an intermetal dielectric layer over the first metal layer; and
forming a second metal layer over the first metal layer and electrically isolated from the first metal layer by the intermetal dielectric layer, wherein the second metal layer comprises a plurality of thermal contacts separated by portions of a top dielectric layer and having upper surfaces with dielectric-free areas.

15. The method of claim 14 wherein the plurality of thermal contacts are connected by connecting portions of the second metal layer.

16. The method of claim 14 wherein:
the plurality of thermal contacts comprises a central contact pad and a plurality of contact traces extending around the contact pad; and
the contact traces overlie corresponding traces in the first metal layer.

17. The method of claim 14 further comprising forming a third metal layer between the first metal layer and the substrate, wherein:
the first and third metal layers are electrically isolated from the second metal layer by the intermetal dielectric layer;
the first and third metal layers are connected by a plurality of vias; and
a plurality of contacts electrically connect the substrate to the third metal layer.

18. The method of claim 17 wherein the first and third metal layers have a same layout.

19. The method of claim 14 further comprising forming a polyimide dam over the plurality of thermal contacts, wherein:
an outer periphery of the polyimide dam laterally surrounds the plurality of thermal contacts; and
the polyimide dam comprises an inner portion and an outer portion surrounding the inner portion and defining an annulus-shaped overflow chamber between the inner and outer portions.

20. The method of claim 14 wherein the IC device does not comprise any transistors.
